(19) United States
(12) Patent Application Publication
(10) Pub. No.: US 2008/0273628 A1
(43) Pub. Date: Nov. 6, 2008

(54) Data sampling circuit and data sampling method

(76) Inventor: Tomoki Kurata, Hamura (JP)

Correspondence Address: ARENT FOX LLP, 1050 CONNECTICUT AVENUE, N.W., SUITE 400, WASHINGTON, DC, 20036, US

(21) Appl. No.: 11/976,811

(22) Filed: Oct. 29, 2007

(30) Foreign Application Priority Data
Dec. 28, 2006 (JP) 2006-356307

(51) Int. Cl. H03D 1/00

(52) U.S. Cl. 375/340

(57) ABSTRACT

A data sampling circuit and a data sampling method for performing sampling at a frequency lower than a carrier frequency. An infrared communication signal converted to an electric signal is input to a data sampling circuit, and a signal in a band lower than or equal to the carrier signal frequency is extracted by an LPF. After the communication signal is input from the LPF, a detection information retention block specifies detection information indicating that the communication signal has been detected and retains the detection information. The detection information in a previous sampling cycle and the detection information in the current sampling cycle are compared to determine whether the communication signal has been input. A measurement block measures a period in which the input of the communication signal continues or a period in which the communication signal is not input, in accordance with the detection result.

### CROSS-REFERENCE TO RELATED APPLICATIONS

This application is based upon and claims the benefits of priority from the prior Japanese Patent Application No. 2006-356307, filed on Dec. 28, 2006, the entire contents of which are incorporated herein by reference.

### BACKGROUND OF THE INVENTION

1. Field of the Invention

The present invention relates to data sampling circuits and data sampling methods, and particularly to a data sampling circuit and a data sampling method for extracting communication data from a communication signal sent by a carrier signal bearing the communication data.

2. Description of the Related Art

Conventional receivers in systems that employ a communication method for transferring communication data on a carrier signal, such as infrared remote control systems, must separate a received communication signal into the carrier signal and the communication data to read the communication data.

Generally, the carrier signal and the communication data can be separated by (1) using special-purpose analog circuits or (2) performing sampling at intervals of up to a half of the cycle of the carrier signal. Examples will be described below.

FIG. 10 shows an example of a conventional data sampling circuit using special-purpose analog circuits.

In the format widely used for general infrared remote controls, communication data is transferred on a 38-kHz carrier signal. Infrared rays (communication signal) 901 have a period in which a signal is output on the carrier signal, or a period of 0.56 milliseconds (ms) in which the signal is kept high, and a period in which the signal is not output, as shown in the figure, and data (“0” or “1”) can be recognized by the ratio between the two periods.

The infrared rays (communication signal) 901 input to a receiver are converted to an electric signal by a photodiode 910 and transferred to a preamplifier 920 for remote control. The transferred signal is amplified by an amplifier 921; a band pass filter (BPF) 922 extracts the carrier signal; and then a detector circuit 923 and a waveform shaping circuit 924 separate the communication data from the carrier signal. The communication data which have been separated from the carrier signal by the preamplifier 920 for remote control is output as a data signal 902 through an input-output (I-O) port 930 to a central processing unit (CPU), which performs signal processing.

FIG. 11 shows an example of a conventional data sampling circuit for performing sampling at intervals of up to a half of the cycle of the carrier signal. Elements identical to those shown in FIG. 10 are denoted by the same reference symbols, and a description of those elements will be omitted.

A communication signal 901 is input to the shown data sampling circuit, as in the case shown in FIG. 10. The infrared rays (communication signal) 901 are converted to an electric signal by a photodiode 910, amplified by an amplifier 921, and output from an I-O port 930 to a CPU, which performs signal processing. An output signal 903 has not yet been separated to the carrier signal and the communication data.

A signal 903a is a magnified carrier wave of a zone in which the output signal 903 is output. As the magnified view shows, the carrier signal in the signal output zone alternates between an ON period (in which the signal is high) of 8.5 microseconds (μs) and an OFF period (in which the signal is low) of 17 μs. This can be detected through sampling at a frequency higher than or equal to three times 38 kHz. Many general household electric appliances use a 32-kHz clock for the internal clock. Sampling cycles for sampling the carrier signal are generated by multiplying the 32-kHz clock signal by four by means of a phase locked loop (PLL) or by providing a special sampling clock signal. This processing is performed by the CPU.

With a receiving circuit proposed to reduce load on the CPU (refer to Japanese Unexamined Patent Application Publication No. Hei-7-38975 (FIG. 1)), the CPU does not read in each sampling cycle. Data detected in each sampling cycle is stored successively in a shift register, and when a complete set of data is stored in the shift register, the CPU performs the processing.

The conventional receiving circuits require special-purpose analog circuits or a sampling frequency higher than the frequency of the carrier signal.

The method of (1) using special-purpose analog circuits tends to increase power consumption because the analog circuits such as a detector circuit and a waveform shaping circuit are included. The presence of the analog circuits leads to a great footprint, which becomes a factor of increase in cost.

The method of (2) performing sampling at intervals of up to a half of the cycle of the carrier signal requires a clock signal having a frequency higher than the carrier frequency in sampling, which also increases power consumption. The method disclosed in Japanese Unexamined Patent Application Publication No. Hei-7-38975 requires a sampling frequency higher than the carrier frequency and poses the same problem.

Especially, the power consumption of infrared remote-control receivers for household electric appliances must be minimized in terms of power saving. Therefore, the power consumption of household electric appliances in the standby state must be minimized. Only a minimum set of indispensable functions such as an internal clock function is kept active. A receiving function for infrared remote control signals must also be kept active in the standby state because the communication signal is sent from the infrared remote control at any time. Therefore, the power consumption of the receiving function for infrared remote control signals must be reduced.

When a communication signal having a high frequency ranging from several hundreds of megahertz to several gigahertz is sampled, the use of the clock signal having a frequency higher than the carrier frequency will increase the power consumption and can also become a factor of noise generation.

### SUMMARY OF THE INVENTION

In view of the foregoing, it is an object of the present invention to provide a data sampling circuit and a data sampling method capable of performing sampling at a frequency close to a carrier frequency or lower.

To accomplish the above object, there is provided a data sampling circuit for extracting communication data from a communication signal sent by a carrier signal bearing the communication data. This data sampling circuit includes the following elements: a detection information retention block for specifying detection information indicating that the communication signal has been detected after the communication signal is input and retaining the detection information for a predetermined period of time; a communication signal detection block for operating in sampling cycles set correspondingly to a frequency close to the carrier signal frequency or lower, storing the detection information in a predetermined storage unit, and determining whether the communication signal has been input until the current sampling cycle by comparing the detection information stored in the storage unit in a previous sampling cycle and the detection information in the current sampling cycle; and a measurement block for measuring a period in which the input of the communication signal continues or a period in which the communication signal is not input, in accordance with whether the communication is detected by the communication signal detection block.

To accomplish the above object, there is provided a receiving apparatus for receiving a communication signal sent by a carrier signal bearing communication data and extracting the communication data from the received communication signal. This receiving apparatus includes the following elements: a receiving block for receiving the communication signal and eliminating components having a higher frequency than the carrier signal included in the received communication signal; a detection information retention block for specifying detection information indicating that the communication signal has been detected after the communication signal is input through the receiving block and retaining the detection information for a predetermined period of time; a communication signal detection block for operating in sampling cycles set correspondingly to a frequency close to the carrier signal frequency or lower, storing the detection information in a predetermined storage unit, and determining whether the communication signal has been input until the current sampling cycle by comparing the detection information stored in the storage unit in a previous sampling cycle and the detection information in the current sampling cycle; a measurement block for measuring a period in which the input of the communication signal continues or a period in which the communication signal is not input, in accordance with whether the communication signal has been detected by the communication signal detection block; and a communication data reproduction block for calculating the period in which the input of the communication signal continues and the period in which the communication signal is not input, in accordance with the measurement results obtained by the measurement block and reproducing the communication data in accordance with the ratio between the period in which the input of the communication signal continues and the period in which the communication signal is not input.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a view showing the concept of the present invention.

FIG. 2A is a view showing a pulse position modulation (PPM) waveform of an infrared remote-control signal processed by data sampling circuits according to embodiments of the present invention.

FIG. 2B is a view showing the waveform of the infrared remote-control signal processed by the data sampling circuits of the embodiments of the present invention.

FIG. 3 is a block diagram showing the structure of a data sampling circuit according to a first embodiment of the present invention.

FIG. 4 is a view showing the operation performed when the input of a communication signal starts in the data sampling circuit of the first embodiment of the present invention.

FIG. 5 is a view showing the operation performed when the input of the communication signal stops in the data sampling circuit of the first embodiment of the present invention.

FIG. 6 is a block diagram showing the structure of a data sampling circuit according to a second embodiment of the present invention.

FIG. 7 is a view showing the operation performed when the input of the communication signal starts in the data sampling circuit of the second embodiment of the present invention.

FIG. 8 is a view showing the operation performed when the input of the communication signal stops in the data sampling circuit of the second embodiment of the present invention.

FIG. 9 is a block diagram showing the structure of a receiving apparatus according to an embodiment of the present invention.

FIG. 10 shows a conventional data sampling circuit using special-purpose analog circuits.

FIG. 11 shows a conventional data sampling circuit for performing sampling at intervals up to a half of the cycle of a carrier signal.

### DESCRIPTION OF THE PREFERRED EMBODIMENTS

Embodiments of the present invention will be described below with reference to the drawings. The concept of the present invention will be described first, and then specific descriptions of the embodiments will be made.

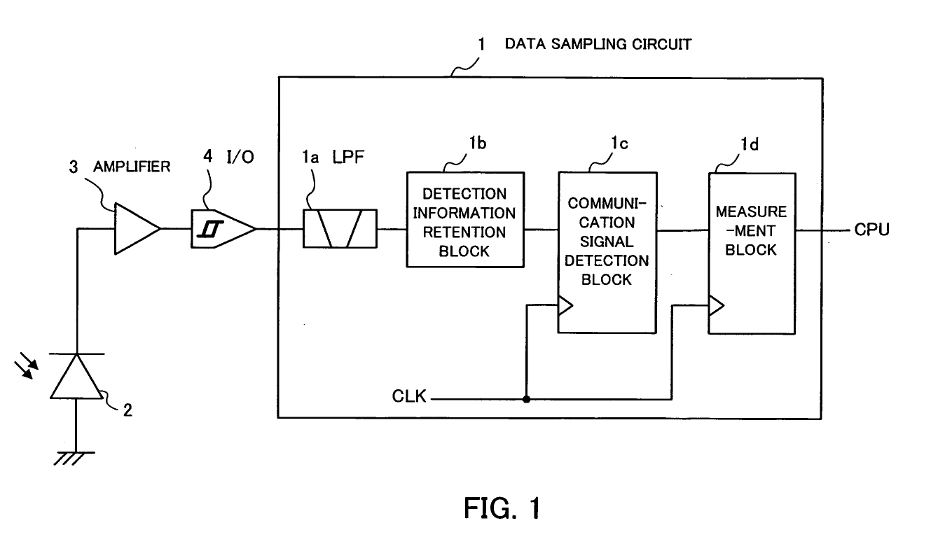

FIG. 1 is a view showing the concept of the present invention.

A data sampling circuit 1 according to the present invention includes a low pass filter (LPF) 1a, a detection information retention block 1b, a communication signal detection block 1c, and a measurement block 1d, and extracts communication data from a communication signal input through a photodiode 2, an amplifier 3, and an I-O port 4. It is supposed that an infrared communication signal sent here represents communication data by a period in which the input of the communication signal continues and a period in which the communication signal is not input.

Each element of the data sampling circuit 1 will next be described.

The LPF 1a is a filter for eliminating components having higher frequencies than the carrier signal, from the communication signal input through the I-O port 4.

When the communication signal is input through the I-O port 4, the detection information retention block 1b specifies detection information indicating that the communication signal has been detected and retains the detection information for a predetermined period of time. The detection information is held at least until the next sampling cycle. If this block is formed by a counter for incrementing its value each time the input is detected, the detection information (counter value) is held until the next communication signal is detected.

The communication signal detection block 1c and the measurement block 1d operate in sampling cycles and sample the communication data. The sampling cycle is set correspondingly to a frequency close to the carrier frequency or lower. Any frequency satisfying this condition can be used, except for such extremely low frequencies that the communication data cannot be sampled.

The communication signal detection block 1c includes a storage unit for storing the detection information and a determination unit for determining whether the communication signal has been input. The storage unit stores the detection information read from the detection information retention block 1b in each sampling cycle and holds the information for a plurality of sampling cycles. When a sampling cycle starts, the communication signal detection block 1c stores new detection information of the current sampling cycle in the storage unit. The determination unit determines whether the communication signal has been input by comparing the detection information in a previous sampling cycle and the detection information in the current sampling cycle. If the detection information is supposed to change each time the communication signal is input and if the detection information of the current sampling cycle differs from the detection information in a previous sampling cycle, it is determined that the communication signal has been input. The determination is reported to the measurement block 1d.

The measurement block 1d checks in each sampling cycle whether the communication signal detection block 1c has detected the communication signal and, if yes, recognizes that the communication signal has been input and updates the input continuation period. If no, or if a no-detection state continues for a certain period of time, it is recognized that the communication signal is not input, and the no-input period is updated. One of the two periods may be measured, and the reproduction of the communication data may be performed finally by a CPU.

Each element for generating the communication signal to be processed by the data sampling circuit 1 will next be described. The photodiode 2 converts a communication signal sent by infrared rays to an electric signal. The amplifier 3 amplifies the electric signal generated by the photodiode 2. The I-O port 4 transfers the electric signal amplified by the amplifier 3 to the data sampling circuit 1 as a communication signal.

The operation of the data sampling circuit 1 structured as described above and a data sampling method will next be described. The infrared communication signal is converted to an electric signal by the photodiode 2, amplified by the amplifier 3, and input to the data sampling circuit 1 through the I-O port 4.

The LPF 1a passes signals in a band lower than or equal to the carrier signal frequency and outputs the signals to the detection information retention block 1b. Therefore, the detection information retention block 1b receives a noise-eliminated communication signal through the LPF 1a. When the communication signal is input, the detection information retention block 1b specifies detection information indicating that the communication signal has been detected and retains the information for a predetermined period of time. When a sampling cycle starts, the communication signal detection block 1c is activated. The communication signal detection block 1c stores the detection information held in the detection information retention block 1b in the storage unit. The stored detection information is referenced in subsequent sampling cycles. The detection information stored in the storage unit in a previous sampling cycle and the detection information in the current sampling cycle are compared to determine whether the communication signal has been input. The measurement block 1d measures the period in which the input of the communication signal continues or the period in which the communication signal is not input, in accordance with the result of measurement. The measurement information is output to the CPU in the next stage. The CPU reproduces the communication data represented by the period in which the input of the communication signal continues and the period in which the communication signal is not input, in accordance with the measurement information.

According to the present invention, the communication data can be sampled in sampling cycles set correspondingly to a frequency close to the carrier signal frequency or lower. As a result, the power consumption and cost can be reduced.

Data sampling circuits according to embodiments of the present invention, applied to a receiver of an infrared remote control for household electric appliances will be described below in detail with reference to the drawings.

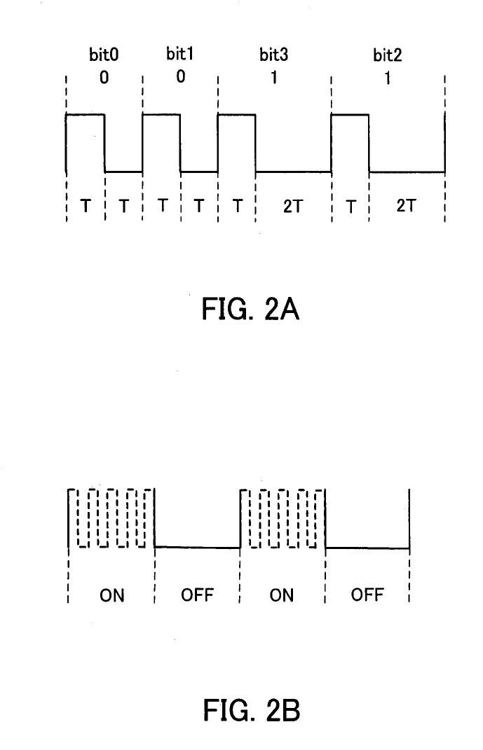

A general infrared remote-control signal used by the infrared remote control for household electric appliances will be described first. FIG. 2A shows a pulse position modulation (PPM) waveform of the infrared remote-control signal processed by data sampling circuits of embodiments of the present invention. FIG. 2B shows an infrared remote-control waveform of the infrared remote-control signal processed by the data sampling circuits of the embodiments of the present invention.

Most infrared remote-control signals use the PPM scheme. In the PPM scheme, a “0” bit and a “1” bit are represented by different pulse intervals, as shown in FIG. 2A. In the shown example, the signal OFF period represents the bit data. A “0” bit is represented by a combination of an ON period of T and an OFF period of T, as in bit 0 and bit 1, and a “1” bit is represented by a combination of an ON period of T and an OFF period of 2T (two times T), as in bit 2 and bit 3. The bit data may also be represented by the length of the signal ON period.

Each ON period has an infrared remote-control waveform as shown in FIG. 2B. The ON period is not given by a continuous infrared ray but by the input of light flashing in carrier wave cycles corresponding to about 38 kHz. The ON period is a period in which the input of the communication signal continues. The OFF period is a period in which the communication signal is not input.

The data sampling circuits of the embodiments of the present invention receive the infrared remote-control signal having the waveform shown in FIG. 2B and generates a data signal having the PPM waveform shown in FIG. 2A.

In two types of data sampling circuits described below, the detection information retention block 1b and the communication signal detection block 1c are configured differently.

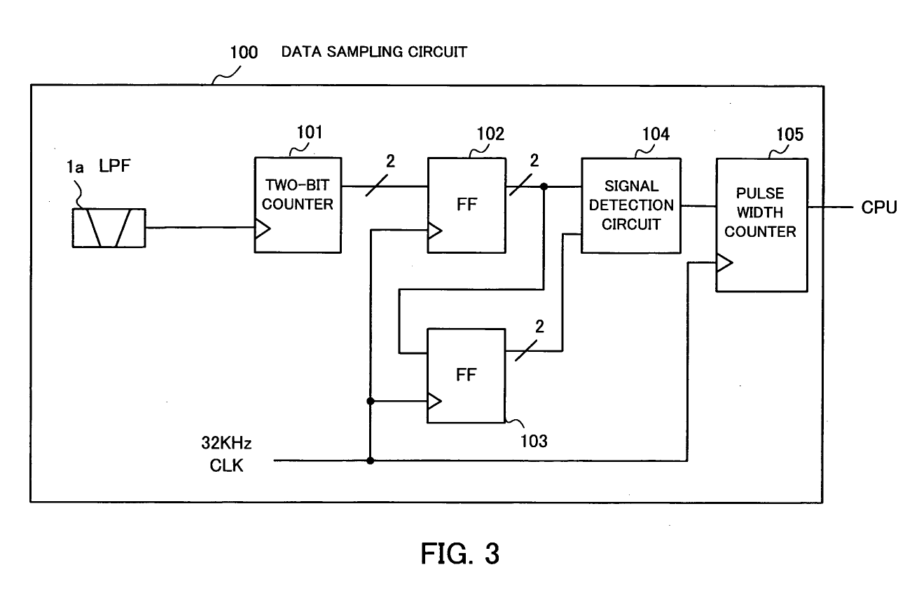

FIG. 3 is a block diagram showing a data sampling circuit of a first embodiment of the present invention. Elements identical to those shown in FIG. 1 are denoted by the same reference symbols, and a description of those elements will be omitted.

A data sampling circuit 100 of the first embodiment of the present invention includes an LPF 1a, a two-bit counter 101, a flip-flop circuit (FF) 102, an FF 103, a signal detection circuit 104, and a pulse width counter 105.

The two-bit counter 101 forms the detection information retention block 1b and holds detection information indicating that a communication signal has been input as a change in counter value. The two-bit counter 101 has an input terminal connected to the LPF 1a and an output terminal connected to the FF 102. The two-bit counter 101 is a cyclic counter, which increments the counter value by one each time the input of the communication signal is detected. As long as the input of a communication signal continues, the output counter value increases. When the input of the communication signal stops, the output counter value does not change. Each time a communication signal is detected, the value of the two-bit counter changes cyclically in order of 0, 1, 2, 3, 0, and so on.

The FF 102 and the FF 103 form the storage unit of the communication signal detection block 1c. The FF 102 has an input terminal connected to the two-bit counter 101 and an output terminal connected to the FF 103 and to the input terminal of the signal detection circuit 104. The FF 103 has an input terminal connected to the FF 102 and an output terminal connected to the signal detection circuit 104. A CLK signal having a sampling frequency (of about 32 kHz) a little lower than the carrier frequency (38 kHz) is input to perform processing in sampling cycles. The 32-kHz CLK signal can be a signal used for the internal clock in general household electric appliances. In each sampling cycle based on the CLK signal, the FF 102 outputs the value of the two-bit counter 101 in the current sampling cycle and holds the value until the next sampling cycle. The FF 103 outputs the value of the two-bit counter 101 in the preceding cycle and holds the value until the next sampling cycle. Accordingly, the signal detection circuit 104 receives the values of the two-bit counter 101 in the preceding sampling cycle and the current sampling cycle.

The signal detection circuit 104 forms the determination unit, which determines whether a communication signal has been input. The circuit compares the value of the two-bit counter 101 in the current sampling cycle, output by the FF 102, and the value of the two-bit counter 101 in the preceding cycle, output by the FF 103, and outputs whether the values are the same. If the values are different, it indicates that the output counter value of the two-bit counter 101 has been changed, and it can be determined that a communication signal has been input.

The pulse width counter 105 forms the measurement block 1d. When the signal detection circuit 104 detects a change in the output counter value, the counter value is incremented by one. With this operation, the pulse width of the period in which the input of the communication signal continues (ON period) is measured, as shown in FIG. 2.

The frequency of the carrier signal does not correspond to the sampling cycle. When the output value of the two-bit counter 101 is sampled in sampling cycles, a change in the counter value is detected if a communication signal is input. The range of the change is determined by the relationship between the carrier frequency and the sampling frequency. If the sampling frequency is lower than the carrier frequency and if a communication signal is input, the output counter value increases unfailingly by one or more. If the sampling frequency is higher than the carrier frequency and if a communication signal is input, the output counter value increases unfailingly by one or more within a certain number of sampling sessions. In the communication data reproduction performed by the CPU in the next stage, whether the communication signal is input or not is analyzed with reference to the communication format used, and the communication data is reproduced accordingly.

The operation of the data sampling circuit 100 of the first embodiment configured as described above will next be described.

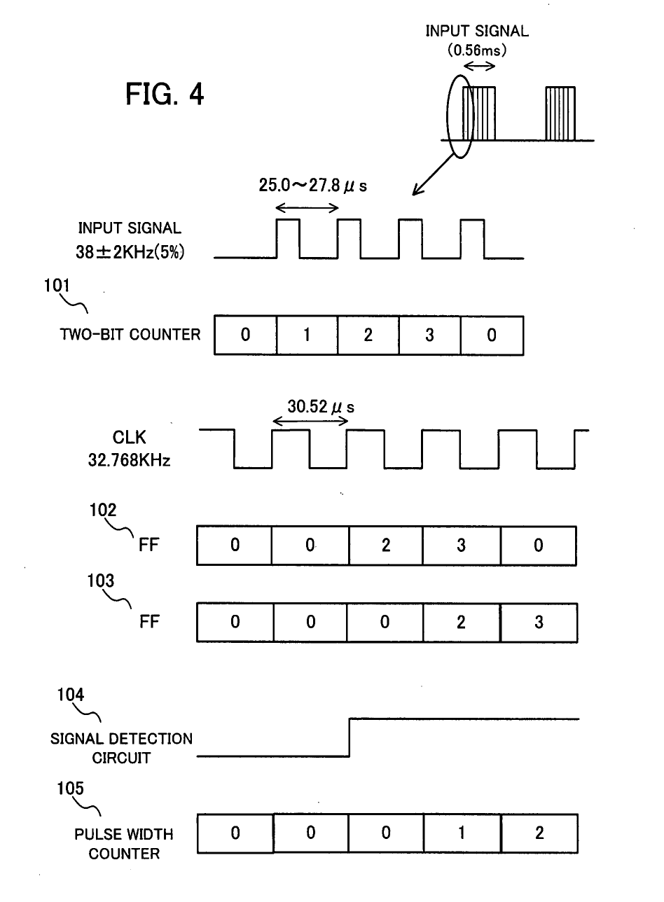

The operation performed when the input of the communication signal starts will be described. FIG. 4 is a view showing the operation performed when the input of the communication signal starts in the data sampling circuit of the first embodiment of the present invention.

The input signal (communication signal) is sent by a carrier signal having a frequency of 38±2 kHz (one cycle is 25.0 to 27.8 μs). The two-bit counter 101 increments the output counter value by one at each rising edge of the communication signal. In the shown example, the counter value changes in order of 0, 1, 2, 3, 0, and so on each time the communication signal is input.

The FF 102, the FF 103, the signal detection circuit 104, and the pulse width counter 105 operate at a sampling frequency of 32.765 kHz (one cycle is 30.52 μs), which is lower than the carrier frequency. This frequency is equivalent to the clock frequency of the internal clock for household electric appliances. As long as the two-bit counter 101 increments with the communication signal detected, the FF 102 and the FF 103 output changing counter values respectively. In comparison with the FF 102, the FF 103 outputs the counter value of one sampling cycle before. While the values of the FF 102 and the FF 103 do not match, the signal detection circuit 104 outputs an ON signal. While the signal detection circuit 104 is ON, the pulse width counter 105 increments the output counter value.

In a subsequent period in which the input of the communication signal continues, the output counter value of the pulse width counter 105 increments in the same manner.

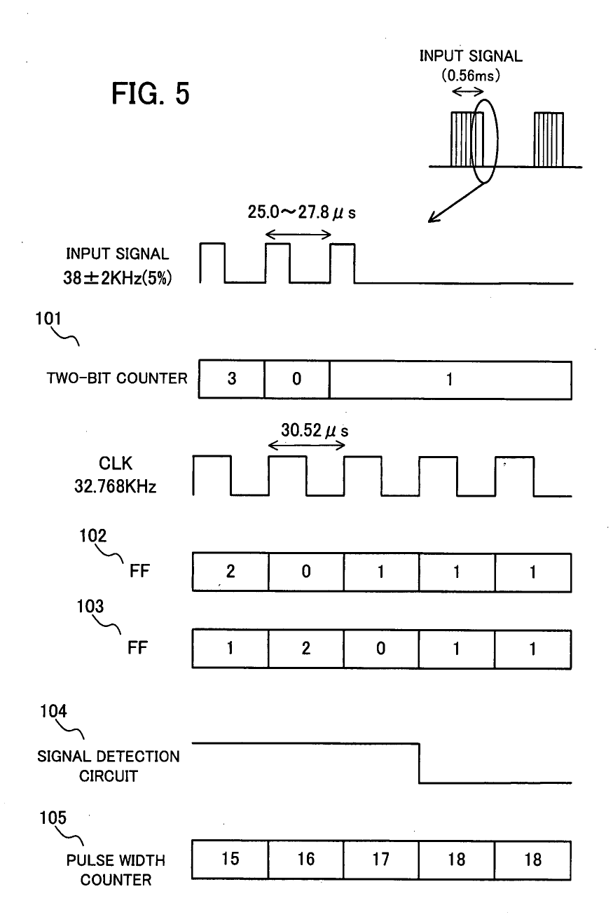

The operation performed when the input of the communication signal stops will next be described. FIG. 5 is a view showing the operation performed when the input of the communication signal stops in the data sampling circuit of the first embodiment of the present invention.

When the input signal (communication signal) stops, the two-bit counter 101 also stops. In the shown example, the counter value “1” set by the last communication signal is held.

While the two-bit counter 101 keeps incrementing with the communication signal detected, the FF 102 and the FF 103 output the changing counter values respectively. When the two-bit counter 101 stops updating the counter value, the FF 102 and the FF 103 also stop updating the output values. In the shown example, both the FF 102 and the FF 103 are set to the last value “1” of the two-bit counter 101. Because the FF 102 and the FF 103 are set to the same value, the signal detection circuit 104 outputs an OFF signal. Because the signal detection circuit 104 is OFF, the pulse width counter 105 stops updating the output counter value. Then, the output counter value of the pulse width counter 105 is not updated before the next communication signal is input.

In the first embodiment, the communication signal which has passed the LPF 1a is regarded as a pulse signal and counted by the two-bit counter 101. The output counter value is sampled in sampling cycles set correspondingly to a frequency lower than the carrier signal frequency, and when the counter value changes, it is determined that the communication signal has been input. In this example, an event that the difference in output counter value between the FF 102 and the FF 103 becomes “3”, which should not occur, may be handled as an error. The period in which the input of the communication signal continues is counted in accordance with the output signal of the signal detection circuit 104 which is held ON while the output counter value keeps changing. By counting the period in which the communication signal is input by using the clock signal for the internal clock, the communication data can be reproduced.

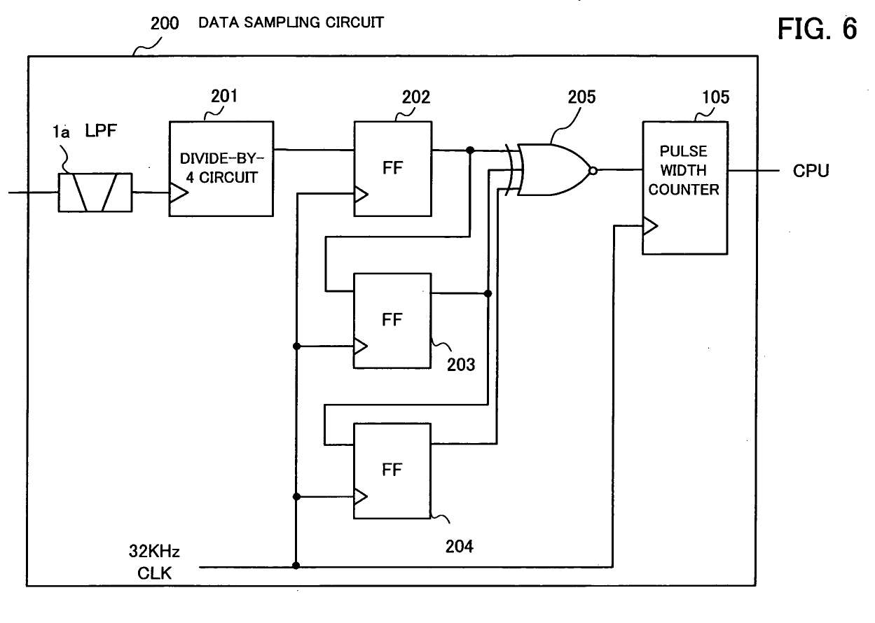

FIG. 6 is a block diagram showing a data sampling circuit of a second embodiment of the present invention. Elements identical to those shown in FIG. 1 or FIG. 3 are denoted by the same reference symbols, and a description of those elements will be omitted.

A data sampling circuit 200 of the second embodiment of the present invention includes an LPF 1a, a divide-by-4 circuit (frequency divider dividing by four) 201, an FF 202, an FF 203, an FF 204, an ExNOR circuit 205, and a pulse width counter 105. The frequency of the input signal and the sampling frequency are supposed to be the same as those in the first embodiment.

The divide-by-4 circuit 201 forms the detection information retention block 1b and has an input terminal connected to the LPF 1a and an output terminal connected to the FF 202. The divide-by-4 circuit 201 divides the frequency of the signal input from the LPF 1a by four and outputs the result to the FF 202. For the purpose of maintaining a status of the communication signal at least until the input of the communication signal can be detected in sampling cycles, the number of stages of the frequency divider is determined such that the output frequency of the frequency divider becomes lower than the sampling frequency. If the sampling frequency is higher than the carrier frequency, the frequency divider may be eliminated.

The FF 202, the FF 203, and the FF 204 are connected in series and form the storage unit of the communication signal detection block 1c. These elements operate in sampling cycles: The FF 202 outputs the output signal of the divide-by-4 circuit 201 in a sampling cycle; the FF 203 outputs the output value of the FF 202 with a delay of one sampling cycle; and the FF 204 outputs the output value of the FF 203 with a delay of one sampling cycle. The values are output to the ExNOR circuit 205.

The ExNOR circuit 205 forms the determination unit of the communication signal detection block 1c. The circuit obtains an EXCLUSIVE-NOR of the outputs of the FF 202, the FF 203, and the FF 204, and outputs the result of the operation to the pulse width counter 105. If the output of the divide-by-4 circuit 201 is sampled in sampling cycles, the output of the divide-by-4 circuit 201 is inverted within a predetermined number of sampling sessions while the input of the communication signal continues. The number of sampling sessions until the output of the frequency divider is inverted is set to a value in a certain range determined by the relationship between the carrier frequency and the sampling frequency. In the example described here, the output of the divide-by-4 circuit 201 is inverted within three sampling sessions while the input of the communication signal continues. The ExNORs of the outputs in three sampling cycles are compared, and if the output of one sampling cycle differs from the other outputs, it is determined that the communication signal is input. If the output of the divide-by-4 circuit 201 is not inverted after the number of sampling sessions exceeds 3, it is determined that the communication signal is not input.

The operation of the data sampling circuit 200 of the second embodiment configured as described above will next be described.

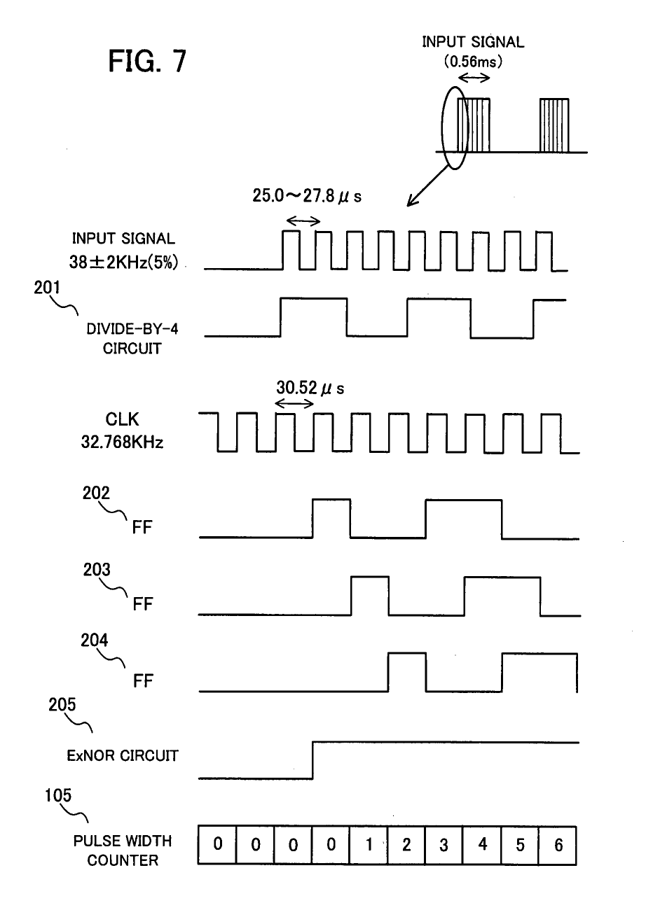

The operation performed when the input of the communication signal starts will be described first. FIG. 7 is a view showing the operation performed when the input of the communication signal starts in the data sampling circuit of the second embodiment of the present invention. The frequency of the input signal (communication signal) and the sampling frequency are supposed to be the same as those in the first embodiment.

The divide-by-4 circuit 201 divides the frequency of the input communication signal by four. The FF 202, the FF 203, the FF 204, the ExNOR circuit 205, and the pulse width counter 105 operate at a sampling frequency lower than the carrier frequency. The FF 202 outputs the status value of the divide-by-4 circuit 201 detected in sampling cycles; and the FF 203 outputs the output status value of the FF 202 with a delay of one sampling cycle. The FF 204 outputs the status value of the FF 203 with a delay of one sampling cycle. The ExNOR circuit 205 outputs an ON signal while the status values of the FF 202, the FF 203, and the FF 204 do not match. While the signal status keeps changing with the input communication signal, the signal status changes within at least three sampling cycles. If the signal status values in three sampling cycles do not match, it is determined that the communication signal is input. While the ExNOR circuit 205 is ON, the pulse width counter 105 increments the output counter value.

In a subsequent period in which the input of the communication signal continues, the output counter value of the pulse width counter 105 is incremented in the same manner.

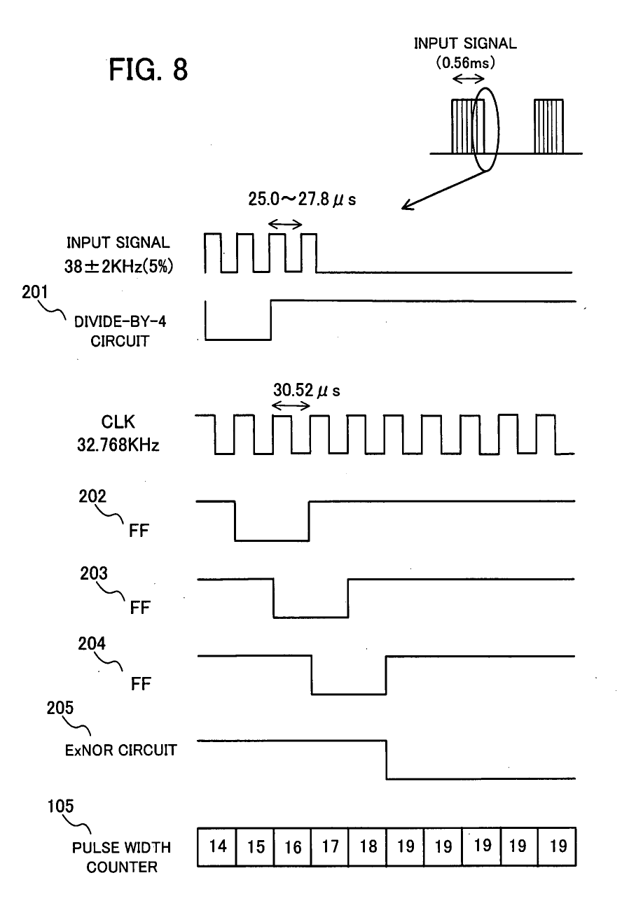

The operation performed when the input of the communication signal stops will next be described. FIG. 8 is a view showing the operation performed when the input of the communication signal stops in the data sampling circuit of the second embodiment of the present invention.

When the input signal (communication signal) stops, the output signal of the divide-by-4 circuit 201 for dividing the frequency of the input signal by four also stops changing the status value. This also stops changes in output signals of the FF 202, the FF 203, and the FF 204 successively. In the shown example, those elements are set to “ON”, which is the last value of the divide-by-4 circuit 201. Because the FF 202, the FF 203, and the FF 204 are set to the same value, the ExNOR circuit 205 outputs an OFF signal. Because the output of the ExNOR circuit 205 is OFF, the pulse width counter 105 stops updating the output counter value. The output counter value of the pulse width counter 105 is not be updated before a new communication signal is input.

As described above, in the second embodiment, the frequency of the communication signal which has passed the LPF 1a is divided by four, and changes in signal status are sampled in sampling cycles set correspondingly to a frequency lower than the carrier signal frequency. If a change in signal status is detected in sampling, it is determined that the communication signal is being input. In the example described above, it is determined that the communication signal is being input if the divided signal is inverted within three sampling sessions, and it is determined that the communication signal is not being input if the divided signal is not inverted within three sampling sessions. The communication data can be reproduced by counting the period in which the communication signal is being input by using the clock signal for the internal clock, in the same way as in the first embodiment.

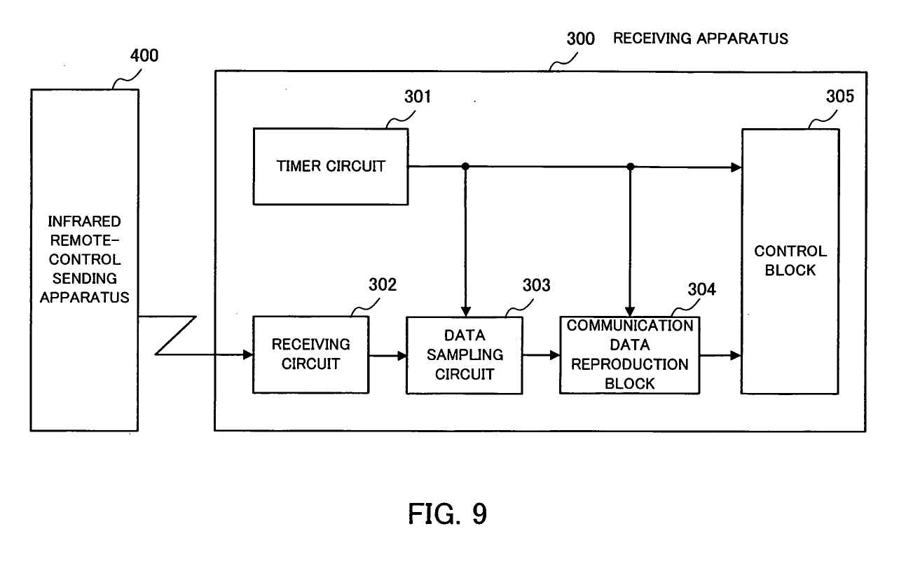

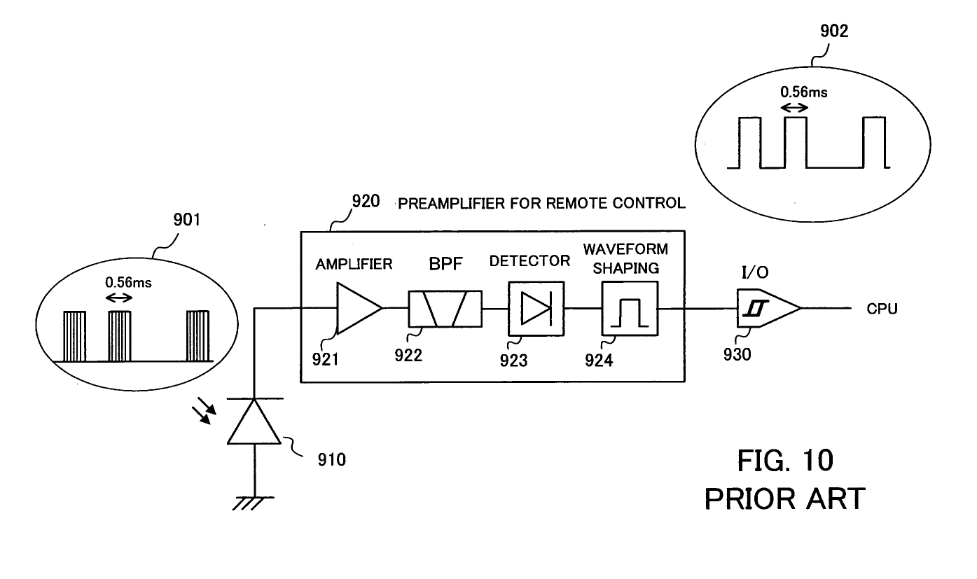

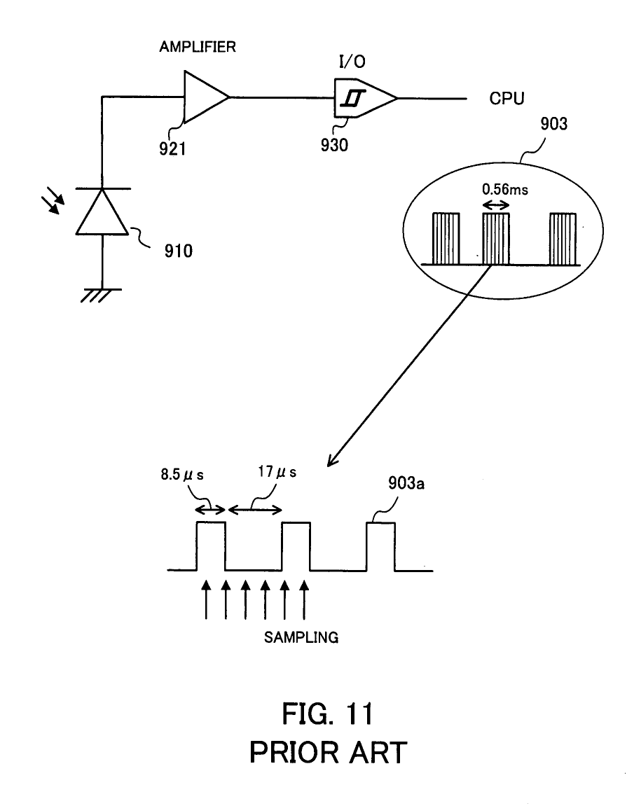

A receiving apparatus which uses a data sampling circuit according to an embodiment of the present invention will next be described. FIG. 9 is a block diagram showing the structure of the receiving apparatus of an embodiment of the present invention.

A receiving apparatus 300 of the embodiment of the present invention includes a timer circuit 301, a receiving circuit 302, a data sampling circuit 303, a communication data reproduction block 304, and a control block 305. The receiving apparatus receives an infrared communication signal sent from an infrared remote-control sending apparatus 400, extracts communication data from the communication signal, and performs predetermined processing depending on the communication data. The communication data reproduction block 304 and the control block 305 are software modules for implementing corresponding processing functions by a program executed by a CPU. The communication signal represents “0” or “1”, depending on the ratio between an “ON” period and an “OFF” period of the communication signal, as shown in FIG. 2.

The timer circuit 301 generates clock pulses having a sampling cycle used to sample remote-control data received from the infrared remote-control sending apparatus 400.

The receiving circuit 302 converts the infrared communication signal sent from the infrared remote-control sending apparatus 400 to an electric signal, adjust the level appropriately, and sends the signal to the data sampling circuit 303. The receiving circuit 302 includes a photodiode, an amplifier, and the like, as shown in FIG. 1.

The data sampling circuit 303 samples the communication signal input through the receiving circuit 302 and performs processing in sampling cycles specified by the timer circuit 301. The circuit is configured as shown in FIG. 3 or FIG. 6. It is supposed that the data sampling circuit 303 outputs a counter value incremented while the communication signal is being input.

The communication data reproduction block 304 reproduces the communication data in accordance with the “ON” period of the communication signal sampled by the data sampling circuit 303.

The control block 305 analyzes an instruction sent from the infrared remote-control sending apparatus 400 in accordance with the communication data reproduced by the communication data reproduction block 304 and executes processing according to the instruction.

The operation of the receiving apparatus 300 configured as described above will be described.

The infrared remote-control sending apparatus 400 sends an infrared remote-control signal by a carrier signal bearing communication data corresponding to instruction information input by the user or the like. In the receiving apparatus 300, the receiving circuit 302 receives the infrared remote-control signal and converts the signal to an electric signal. When the converted communication signal is input to the data sampling circuit 303, detection information indicating that the communication signal has been input is generated. The data sampling circuit 303 starts data sampling by using the clock pulse having a sampling frequency generated by the timer circuit 301. In the data sampling processing, it is determined whether the communication signal has been input after a previous sampling cycle until the current sampling cycle, in accordance with the detection information. If the communication signal has been detected, the counter for counting the input continuation time is incremented. If the communication signal has not been detected, the counter value does not change. The communication data reproduction block 304 calculates a period in which the input of the communication signal continues and a period in which the communication signal is not input, in accordance with the counter value set by the data sampling circuit 303, and reproduces the communication data accordingly. The communication data is output to the control block 305. The control block 305 executes processing based on the communication data.

As described above, the receiving apparatus 300 using a data sampling circuit of an embodiment of the present invention can execute processing in data sampling cycles generated by the clock signal for the internal clock or the like, which is close to the carrier signal frequency. This eliminates the need for a timer circuit for generating a high-frequency clock pulse for data sampling, which allows a cost reduction.

According to the present invention, the input of the communication signal is held as detection information, and sampling for extracting communication data is performed in sampling cycles corresponding to a frequency close to the carrier signal frequency or lower. The communication signal is detected by comparing the detection information in the current sampling cycle and the detection information in a previous sampling cycle, and the period in which the input of the communication signal continues is measured. The communication data can be extracted with reference to the period in which the input of the communication signal continues and the period in which the communication signal is not input. According to the present invention, sampling can be performed not in a conventional short sampling cycle corresponding to a half of the cycle of the carrier frequency but in a long sampling cycle close to the cycle of the carrier frequency, so that the power consumption can be reduced. Analog circuits such as a detector circuit and a waveform shaping circuit are not necessary, and the cost for the analog circuits can be reduced.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A data sampling circuit for extracting communication data from a communication signal sent by a carrier signal bearing the communication data, the data sampling circuit comprising:
a detection information retention block for specifying detection information indicating that the communication signal has been detected after the communication signal is input and retaining the detection information for a predetermined period of time;
a communication signal detection block for operating in sampling cycles set to a cycle corresponding to a frequency close to the frequency of the carrier signal or lower, storing the detection information in predetermined storage means, and determining whether the communication signal has been input by the current sampling cycle by comparing the detection information stored in the storage means in a previous sampling cycle and the detection information in the current sampling cycle; and
a measurement block for measuring a period in which the input of the communication signal continues or a period in which the communication signal is not input, depending on whether the communication signal detection block has detected the communication signal.

2. The data sampling circuit according to claim 1, wherein the measurement block operates in the sampling cycles and measures the period by means of a counter for incrementing its counter value if the communication signal detection block detects the communication signal.

3. The data sampling circuit according to claim 1, wherein the detection information retention block is formed by a cyclic counter for updating its counter value each time the input of the communication signal is detected.

4. The data sampling circuit according to claim 3, wherein the communication signal detection block comprises:
first counter storage means for storing the value of the cyclic counter in the current sampling cycle;
second counter storage means for storing the value of the cyclic counter in the preceding sampling cycle; and
a determination block for comparing the value of the cyclic counter stored in the first counter storage means and the value of the cyclic counter stored in the second counter storage means and determining that the communication signal has been input if the two values are different.

5. The data sampling circuit according to claim 4, wherein the first counter storage means and the second counter storage means are formed by flip-flop circuits, the first counter storage means having an input terminal connected to an output terminal of the cyclic counter, the second counter storage means having an input terminal connected to an output terminal of the first counter storage means.

6. The data sampling circuit according to claim 1, wherein the detection information retention block is formed by a frequency divider for dividing the frequency of the input communication signal and retaining the waveform of the communication signal for a period longer than the sampling cycle.

7. The data sampling circuit according to claim 6, wherein the communication signal detection block comprises:
first signal status storage means for storing a status of the communication signal output by the frequency divider in the current sampling cycle;
second signal status storage means for storing a status of the communication signal output by the frequency divider in a previous sampling cycle; and
a determination block for comparing the status of the communication signal stored in the first signal status storage means and the status of the communication stored in the second signal status storage means and determining that the communication signal has been input if a change is detected.

8. The data sampling circuit according to claim 7, wherein the second signal status storage means specifies the number of areas corresponding to the number of sampling sessions produced in sampling cycles before the output signal of the detection information retention block is inverted while the input of the communication signal continues.

9. The data sampling circuit according to claim 1, further comprising a low-pass filter for eliminating components having a higher frequency than the carrier signal from the communication signal and outputting the result to the detection information retention block.

10. The data sampling circuit according to claim 1, wherein the data sampling circuit uses a clock signal for an internal clock of household electric appliances to determine the sampling cycle, the clock signal being applied to a receiving circuit of an infrared remote control for household electric appliances and having a frequency close to the frequency of the carrier signal of an infrared remote-control signal used for the infrared remote control.

11. The data sampling circuit according to claim 1, wherein the sampling cycle is set correspondingly to a frequency lower than the frequency of the carrier signal.

12. A data sampling method for extracting communication data from a communication signal sent by a carrier signal bearing the communication data; the data sampling method comprising the steps of:
a detection information retention block specifying detection information indicating that the communication signal has been detected after the communication signal is input and retaining the detection information for a predetermined period of time;
a communication signal detection block operating in sampling cycles set to a cycle corresponding to a frequency close to the frequency of the carrier signal or lower, storing the detection information in predetermined storage means, and determining whether the communication signal has been input by the current sampling cycle by comparing the detection information stored in the storage means in a previous sampling cycle and the detection information in the current sampling cycle; and
a measurement block measuring a period in which the input of the communication signal continues or a period in which the communication signal is not input, depending on whether the communication signal detection block has detected the communication signal.

13. A receiving apparatus for receiving a communication signal sent by a carrier signal bearing communication data and extracting the communication data from the received communication signal, the receiving apparatus comprising:
a receiving block for receiving the communication signal and eliminating components having a higher frequency than the carrier signal included in the received communication signal;
a detection information retention block for specifying detection information indicating that the communication signal has been detected after the communication signal is input through the receiving block and retaining the detection information for a predetermined period of time;
a communication signal detection block for operating in sampling cycles set to a cycle corresponding to a frequency close to the frequency of the carrier signal or lower, storing the detection information in predetermined storage means, and determining whether the communication signal has been input by the current sampling cycle by comparing the detection information stored in the storage means in a previous sampling cycle and the detection information in the current sampling cycle;
a measurement block for measuring a period in which the input of the communication signal continues or a period in which the communication signal is not input, in accordance with whether the communication signal has been detected by the communication signal detection block; and
a communication data reproduction block for calculating the period in which the input of the communication signal continues and the period in which the communication signal is not input, in accordance with the measurement result of the measurement block and reproducing the communication data, depending on a ratio between the period in which the input of the communication signal continues and the period in which the communication signal is not input.
